(19) United States
(12) Patent Application Publication
(10) Pub. No.: US 2025/0085581 A1
(43) Pub. Date: Mar. 13, 2025

(54) POLARIZER, PREPARATION METHOD THEREOF, AND DISPLAY PANEL

(71) Applicant: TCL CHINA STAR OPTOELECTRONICS TECHNOLOGY CO., LTD., Shenzhen, Guangdong (CN)

(72) Inventor: Hongshan YIN, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 18/548,512

(22) PCT Filed: Aug. 10, 2023
(86) PCT No.: PCT/CN2023/112295

§ 371 Date: Aug. 31, 2023

(30) Foreign Application Priority Data
Apr. 13, 2023 (CN) 202310394344.4

(51) Int. Cl. G02F 1/1335; G02B 5/02; G02B 5/30

(52) U.S. Cl. CPC G02F 1/133504; G02B 5/0205; G02B 5/0268; G02B 5/3025; G02F 1/133528

(57) ABSTRACT

A polarizer includes a polarizing functional layer and a whisker arranged within the polarizing functional layer. After dyeing and stretching, the polarizing functional layer converts natural light into polarized light, and the whiskers are directionally arranged within the polarizing functional layer. The whisker has a long axis, and the extension direction of the long axis has an angle of −5 degrees to 5 degrees with the absorption axis of the polarizing functional layer. The present disclosure also provides a method for preparing a polarizer, and a display panel having a polarizer.

### FIELD OF THE INVENTION

The present disclosure relates to the field of display technology, more particularly, to a polarizer, a preparation method thereof, and a display panel.

### BACKGROUND

With the development of liquid crystal display (LCD) technology, liquid crystal display panels tend to have large sizes and uniform contrast. However, due to the uneven distribution of liquid crystal molecules, the light transmittance of liquid crystal display panels varies at different angles, resulting in distorted display colors. The display effect of the middle part of the LCD panel is the best, and the chromaticity and hue at a distance away from the centerline in the vertical direction differ greatly from the chromaticity and hue at the middle part, leading to serious color deviation. In existing technology, to improve the issue of chromaticity perspective, a diffusion film and a light intensity compensation film are attached to the LCD panel to evenly diffuse the light of the LCD panel and compensate for the light intensity at certain angles. However, the improvement effect of this method is relatively limited.

To expand the viewing angle of liquid crystal display panels to adapt to large-sized screens, a new polarizer, and its preparation method, as well as a display panel, need to be proposed, which can expand the viewing angle range of liquid crystal display panels and improve the chromaticity viewing angle.

### Technical Problem

The purpose of the present disclosure is to provide a polarizer and its preparation method, as well as a display panel, which can expand the viewing range of a liquid crystal display panel, improve the chromaticity viewing angle, and make the chromaticity and hue under a large viewing angle close to those under a positive viewing angle, thereby improving display quality.

### Technical Solution

To address the aforementioned technical issues, the present disclosure provides a polarizer, which includes a polarizing functional layer and a whisker arranged within the polarizing functional layer. The polarized functional layer after dyeing and stretching converts natural light into polarized light, and the whiskers are arranged in a directional manner within the polarized functional layer. The whisker has a long axis, and the angle between the extension direction of the long axis and the absorption axis of the polarizing functional layer is −5 degrees to 5 degrees.

In one embodiment of the present disclosure, the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker.

In one embodiment of the present disclosure, a material of the polarizing functional layer comprises polyvinyl alcohol.

In one embodiment of the present disclosure, a mass percentage of the whisker in the polarizing functional layer is M1, 0%<M1<80%.

In one embodiment of the present disclosure, the whisker accounts for a mass percentage of 10% of the polarizing functional layer.

In one embodiment of the present disclosure, an acute angle is formed between the extension direction of the long axis of the whisker and the bottom surface of the polarizing functional layer, and the acute angle is greater than 0 degree and less than or equal to 40 degree.

In one embodiment of the present disclosure, the acute angle is greater than 0 degree and less than or equal to 20 degrees.

In one embodiment of the present disclosure, the long axis is 5 microns to 100 microns, the whisker has a short axis, and the short axis is 0.5 microns to 1 microns.

In one embodiment of the present disclosure, the whisker comprises a main body and a modified group connected to the surface of the main body, the structural formula of the modified group is —X—A—R, where X is selected from SO₃ or PO₄H, A is selected from a single bond, a substituted or unsubstituted aromatic group with a ring atomic number of 6-20, or an imidazoline group, and R is selected from a substituted or unsubstituted alkyl group with a carbon atomic number of 2-20, and a substituted or unsubstituted siloxane alkyl group with a carbon atomic number of 2-20, Alkyl alcohol amide groups with a carbon atom number of 2-20.

In one embodiment of the present disclosure, the general structural formula of R is

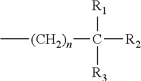

that R₁, R₂, and R₃ are independently selected from F, Cl, Br, I, or H, and n is an integer from 1 to 19.

In one embodiment of the present disclosure, R₁, R₂, and R₃ are independently selected from For H, and at least one of R₁, R₂, and R₃ is selected from F; and/or
X selected from SO₃; and/or
A is selected from substituted or unsubstituted aromatic groups with a ring atomic number of 6-20.

In one embodiment of the present disclosure, the modified group is selected from at least one of the following structural formulas:

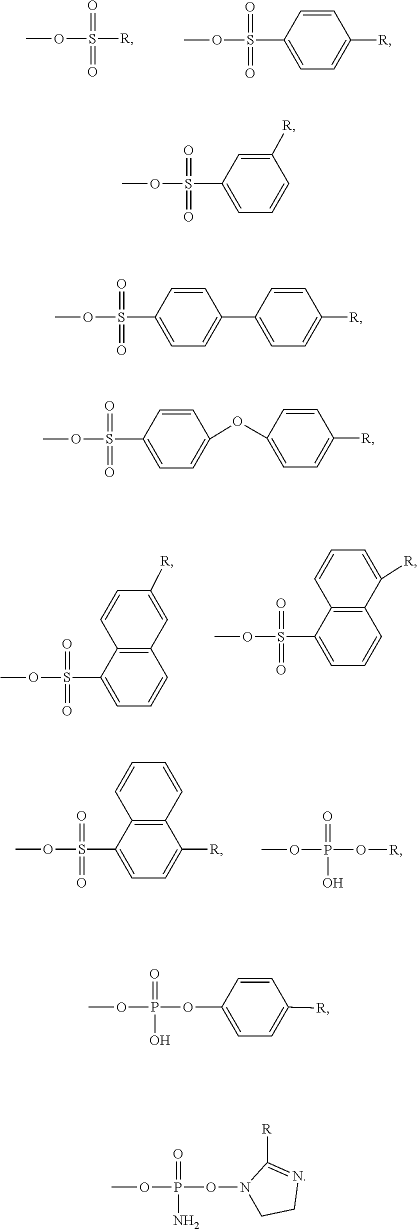

In one embodiment of the present disclosure, a difference in refractive index between the whisker and the polarizing functional layer is greater than 0 and less than or equal to 0.5; and/or the refractive index of the whisker is greater than or equal to 1.5 and less than or equal to 2.0.

The present disclosure also provides a method for preparing a polarizer, comprising:
mixing polarizing materials and whiskers to form a polarizing substrate, wherein the whiskers have a long axis; and
stretching the polarizing substrate to form a polarizing functional layer, so that the whiskers are oriented and arranged, and the angle between the extension direction of the long axis and the absorption axis of the polarizing functional layer is −5 degrees to 5 degrees.

In one embodiment of the present disclosure, after the step of mixing the polarizing material and whiskers to form a polarizing substrate, and before the step of stretching the polarizing substrate to form a polarizing functional layer, the method further comprises cleaning, expanding, and dyeing the polarizing substrate.

In one embodiment of the present disclosure, the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker.

In one embodiment of the present disclosure, a material of the polarizing functional layer comprises polyvinyl alcohol.

In one embodiment of the present disclosure, the whisker accounts for a mass percentage of 10% of the polarizing functional layer.

The present disclosure also provides a display panel. The display panel includes a panel body and a polarizer attached to the panel body. The polarizer includes a polarizing functional layer and a whisker arranged within the polarizing functional layer. The polarized functional layer after dyeing and stretching converts natural light into polarized light, and the whiskers are arranged in a directional manner within the polarized functional layer. The whisker has a long axis, and the angle between the extension direction of the long axis and the absorption axis of the polarizing functional layer is −5 degrees to 5 degrees.

In one embodiment of the present disclosure, the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker.

A material of the polarizing functional layer comprises polyvinyl alcohol.

### Advantageous Effect

Due to the stretching of the polarizing substrate containing whiskers during the preparation process, the polarizing substrate has a polarizing effect while changing the disordered arrangement of whiskers into an ordered arrangement. The polarizer formed in this way has an angle between −5 degrees and 5 degrees between the long axis extension direction of the whisker and the absorption axis extension direction of the polarizing functional layer. The arrangement of whiskers in the polarizer will cause Mie scattering of light to pass through the polarizer in the direction perpendicular to the absorption axis. When the polarizer is attached to the display film layer, the visual angle of the display panel expands in the direction perpendicular to the absorption axis, which means the viewing range is expanded. At the same time, the chromaticity angle is improved, so that the chromaticity and hue under a large viewing angle are close to those under a positive viewing angle, and the display quality is improved.

### BRIEF DESCRIPTION OF THE DRAWINGS

FIG. 1 is a schematic diagram of a structure of a polarizer according to one embodiment of the present disclosure.

FIG. 2 is a schematic diagram of a top view structure of the polarizer according to one embodiment of the present disclosure. and scale number.

FIG. 3 is a schematic diagram of the relationship between Mie scattering intensity

FIG. 4 is a schematic diagram of the arrangement of whiskers in the polarizing functional layer of the polarizer according to one embodiment of the present disclosure.

FIG. 5 shows the modification mechanism of alkyl benzenesulfonic acid based modifiers.

FIG. 6 is a structural schematic diagram of a surface modified calcium carbonate whisker in the polarizer according to one embodiment of the present disclosure.

FIG. 7 is another structural schematic diagram of the surface modified calcium carbonate whisker in the polarizer according to one embodiment of the present disclosure.

FIG. 8 shows the modification mechanism of alkyl phosphate ester modifiers.

FIG. 9 is a flowchart of a preparation method for the polarizer according to one embodiment of the present disclosure.

FIG. 10 is a schematic diagram of the operation of step S1 according to one embodiment of the present disclosure.

FIG. 11 is a schematic diagram of the operation of steps P1 to P5 according to one embodiment of the present disclosure.

FIG. 12 is a structural schematic diagram of a display panel according to one embodiment of the present disclosure.

### REFERENCE SIGNS

Polarizer 10; Polarizing functional layer 11; Bottom surface 11a; Top surface 11b; Whisker 12; Diffusor layer 13; Glue layer 13J; Protective film 14; Polarizing substrate J1; Absorption axis Z; Display panel 100; Panel body 20; Thickness of polarizing functional layer H; Length of whisker L.

### DESCRIPTION OF THE EMBODIMENTS

The following will be combined with the accompanying drawings in the embodiment of the present disclosure, the technical solution in the embodiment of the present disclosure is clearly and completely described. Obviously, the described embodiment is only a part of the embodiments of the present disclosure, not all embodiments. Based on the embodiments in the present disclosure, all other embodiments obtained by those skilled in the art without performing creative labor are within the scope of protection of the present disclosure.

It should be noted that in the description of the present disclosure, it is necessary to understand that the orientation or position relationship belonging to the indication of “up”, “down”, “front”, “back”, “left”, “right”, “inside”, “outside” and so on is based on the orientation or position relationship illustrated in the drawings, only to facilitate the description of the present disclosure and simplify the description, not to indicate or imply that the device or element referred to must have a specific orientation, constructed and operated in a specific orientation. So it cannot be understood as a restriction on the present disclosure.

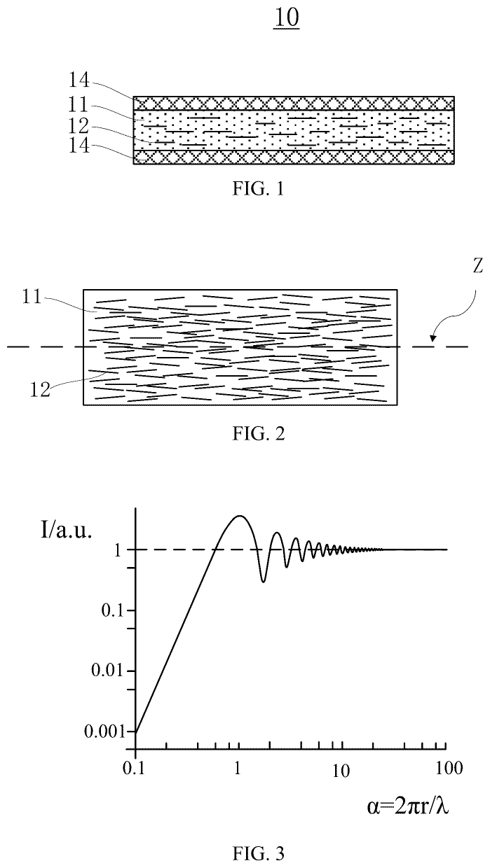

Please refer to FIGS. 1 and 2, an embodiment of the present disclosure provides a polarizer 10. The polarizer 10 includes a polarizing functional layer 11 and a whisker 12 disposed in the polarizing functional layer 11. The polarizing functional layer 11 after dyeing and stretching is used to convert natural light into polarized light. The whisker 12 is oriented within the polarizing functional layer 11. The polarizing functional layer 11 has an absorption axis Z. The whisker 12 has a long axis, and the angle between the extension direction of the long axis and the absorption axis Z of the polarizing functional layer ranges between −5 degrees and 5 degrees. Specifically, the angle between the extension direction of the long axis of the whisker 12 and the absorption axis Z of the polarization functional layer can be −5 degrees, −3 degrees, −1 degrees, 0 degrees, 1 degrees, 3 degrees, 5 degrees, etc.

In the present disclosure, the angle formed by counterclockwise rotation of the absorption axis Z of the polarizing functional layer 11 centered on a certain point on the absorption axis Z is a negative angle, and the angle formed by clockwise rotation centered on that point is a positive angle. When the angle between the extension direction of the long axis of whisker 12 and the extension direction of the absorption axis Z of the polarizing functional layer is −5 degrees, the absorption axis Z of the polarizing functional layer 11 rotates counterclockwise 5 degrees from a certain point on the absorption axis Z to form a straight line parallel to the long axis of whisker 12. When the angle between the extension direction of the long axis of whisker 12 and the extension direction of the absorption axis Z of the polarizing functional layer is 5 degrees, the absorption axis Z of the polarizing functional layer 11 rotates clockwise 5 degrees from a certain point on the absorption axis Z to form a straight line parallel to the long axis of whisker 12.

During the preparation process of this embodiment, the polarizing substrate J1, including whiskers 12, is stretched to have a polarizing effect. At the same time, the whiskers 12 in the polarizer 10 are changed from a disordered arrangement to an ordered arrangement. The polarizer 10 formed in this way has an angle between −5 degrees and 5 degrees between the long axis extension direction of the whisker 12 and the absorption axis Z extension direction of the polarizing functional layer. The arrangement of whisker 12 in polarizer 10 will cause Mie scattering of light passing through polarizer 10 in the direction perpendicular to the absorption axis Z. When the polarizer 10 is attached to the display film layer, the visual angle of the display panel 100 expands in the direction perpendicular to the absorption axis Z, that is, the viewing range expands. At the same time, improve the chromaticity perspective, so that the chromaticity and hue under a large viewing angle are close to those under a positive viewing angle, improving display quality.

In this embodiment, the long axis of whisker 12 is 5 microns to 100 microns, and the short axis of whisker 12 is 0.1 microns to 10 microns. Specifically, the long axis of whisker 12 can be 5 micrometers, 10 micrometers, 50 micrometers, 80 micrometers, or 100 micrometers, while the short axis of whisker 12 can be 0.1 micrometers, 0.5 micrometers, 1 micrometer, 5 micrometers, 6 micrometers, or 10 micrometers.

It should be noted that Mie scattering refers to the scattering of light mainly in the direction it originally travels when it reaches particles with a diameter equal to or larger than the wavelength of light. The intensity change of scattering is a function of the ratio of particle radius to radiation wavelength, citing dimensionless scale numbers α as a discriminant criterion, the formula is α=2πr/λ, where a is the dimensionless scale number, r is the particle radius, and λ is the wavelength of light.

Please refer to FIG. 3, which is a schematic diagram of the relationship between Mie scattering intensity and scale number, where the abscissa represents the scale number α, and the ordinate is the scattering intensity I. For example, if whisker 12 is needle-shaped, the short axis of whisker 12 is the diameter. When the number of scales α is 1, the Mic scattering intensity I reaches its maximum. When the number of scales α is greater than 1, the scattering intensity I tend to stabilize around 1. Because the light emitted by the display screen needs to be visible to the human eye, that is, the visible light emitted by the display screen has a wavelength of 380 nanometers to 780 nanometers. To make the scale number α is greater than 1, the diameter of whisker 12 should be greater than 0.121 microns to 0.248 microns. Therefore, the short axis of whisker 12 is between 0.1 microns and 10 microns, and the intensity of Mie scattering is high, which means the intensity of light scattering is high. Therefore, when the polarizer 10 is attached to the display film layer, the contrast of the large viewing angle range is improved.

In addition, the scattering that occurs when light reaches particles with wavelengths equivalent to or larger than light waves is called Mie scattering. In order for Mie scattering to occur, whisker 12 needs to grow larger than light waves. Therefore, when the short axis of whisker 12 is less than 390 nanometers to 780 nanometers, the long axis length of whisker 12 needs to increase, which can be selected from 5 microns to 100 microns.

The short axis of whisker 12 is selected from 0.5 micrometers to 1 micrometer, and the long axis is selected from 5 micrometers to 100 micrometers. While ensuring the occurrence of Mie scattering, it can reduce light loss caused by the excessive area of whisker 12.

Optionally, the mass percentage of whisker 12 set within the polarizing functional layer 11 is M1, with 0%<M1<80%.

The mass percentage of solidified whisker 12 in the polarizing functional layer 11 is M1, with 0%<M1<80%, which can increase the light diffusion angle. Optional, M1 can be 8%, 10%, 15%, 20%, 25%, 30%, 50%, or 60%, etc.

In this embodiment, the whisker 12 located within the polarizing functional layer 11 accounts for 10% of the mass percentage of the polarizing functional layer 11. This polarizing plate 10 can be arranged on the panel body 20 to expand the viewing angle of the display panel from 100 to more than 160 degrees.

When the proportion of whisker 12 in the polarizing functional layer 11 is relatively small, the scattering effect is weak, which can improve the contrast of the side view of the display panel 100. However, there is still a gap between the contrast of the side view and the positive view. When the proportion of whisker 12 in the polarizing functional layer 11 is large, the scattering effect is strong, and more light is scattered to the side view angle, resulting in a decrease in the light transmittance of the front of the polarizing plate 10, resulting in lower brightness of the positive view angle screen.

In this embodiment, the material of the polarizing functional layer 11 comprises polyvinyl alcohol.

Understandably, polyvinyl alcohol (PVA) film has a polarizing effect after stretching, which can convert natural light into polarized light for emission. Setting whiskers 12 in the polyvinyl alcohol film and forming a polarizing functional layer 11 after stretching can have both polarizing and scattering effects, which is beneficial for saving the film layer.

Optionally, the polarizer 10 can also include a protective film 14 attached to the surface of the polarizing functional layer 11. The protective film 14 can be made of Triacetyl Cellulose (TAC) film to protect the polarizing functional layer 11, but the present disclosure is not limited to this.

In this embodiment, whisker 12 is selected from one of calcium carbonate whiskers, barium sulfate whiskers, titanium oxide whiskers, and alumina whiskers.

Adding low-cost whiskers 12 to the polarizing functional layer 11 can effectively reduce the production cost of polarizer 10. Materials such as calcium carbonate, barium sulfate, titanium oxide, and alumina are cheap and cost-effective. Directly adding whiskers 12 selected from calcium carbonate, barium sulfate, titanium oxide, alumina, etc. to the polarizing functional layer 11 reduces the cost by more than 50% compared to attaching a light intensity compensation film or other film layers on the polarizer 10. It is understandable that whisker 12 can also be selected from other materials, such as zirconia, zinc oxide, boehmite, aluminum borate, calcium silicate, magnesium sulfate, magnesium sulfate hydrate, potassium titanate, etc. The present disclosure does not limit this.

Whisker 12 can be cylindrical or conical, for example, cylindrical, elliptical, triangular, quadri-prism, multi prism, triangular, quadrigrams, or multi prism. The extension direction of the long axis of the whisker represents the height direction of the column or cone, and the length L represents the length in the height direction of the column or cone, also known as the length in the long axis direction.

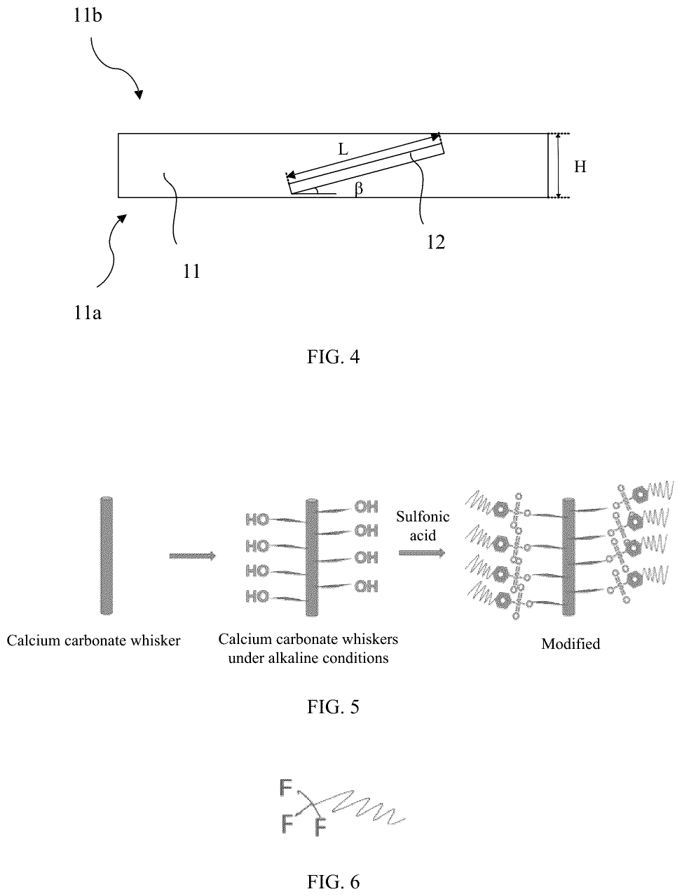

Please refer to FIG. 4. The thickness of polarizing functional layer 11 is H, the length of whisker 12 is L, and the direction of the long axis extension of whisker 12 forms an acute angle with the bottom surface 11a β Within the range of −arcsin (H/L) to arcsin (H/L). The inventor discovered through research that acute angles β It has an impact on the optical performance of polarizer 10.

The polarizing functional layer 11 comprises a bottom surface 11a and a top surface 11b that are opposite in the direction of the film layer stacking. Optionally, the bottom surface 11a is located on the incoming side of the top surface 11b, or the bottom surface 11a is the surface formed first when forming the polarizing functional layer 11. When the direction of the long axis extension of whisker 12 forms an acute angle with the bottom surface 11a β If the size of whisker 12 is too large, due to the limitation of the thickness of the polarizing functional layer 11 film, it will cause the protrusion of whisker 12 in the polarizing functional layer 11, affecting the smoothness of the film layer. In addition, if the length of whisker 12 is too long, it can easily lead to excessive aggregation of whisker 12 and affect its appearance.

Specifically, when adding whisker 12 to polarizer 10, the sharp angle between the extension direction of the long axis of whisker 12 and the bottom surface 11a β When the angle is greater than 0 degree and less than or equal to 40 degree, it is beneficial to improve the brightness and chromaticity perspectives. Specifically, it may be due to the fixed length of whisker 12, which results in a fixed amount of light scattering by whisker 12. The scattering amount of light by whisker 12 can be divided into the components of whisker 12 in the direction parallel to the bottom surface 11a of the polarizing functional layer 11 (referred to as the left and right components) and the components in the direction perpendicular to the bottom surface 11a of the polarizing functional layer 11 (referred to as the upper and lower components). If the left and right components are large, the upper and lower components are small. When the angle between whisker 12 and polarizing functional layer 11 is smaller, the left and right components are larger (i.e., the projection of whisker 12 on polarizing functional layer 11 is larger), the left and right scattering is stronger, and the left and right angle performance is better, and vice versa.

Furthermore, the experimental results indicate that the sharp angle β between the extension direction of the long axis of whisker 12 and the bottom surface 11a is less than or equal to 20 degrees. The brightness and chromaticity perspectives have been further improved.

Optionally, whisker 12 comprises a host and a modified group connected to the surface of the host. The structural formula of the modified group is —X—A—R, where X is selected from SO₃ or POH, A is selected from a single bond, a substituted or unsubstituted aromatic group with a ring atomic number of 6-20, or an imidazoline group, R is selected from a substituted or unsubstituted alkyl group with a carbon atomic number of 2-20, a substituted or unsubstituted siloxane alkyl group with a carbon atomic number of 2-20, or an alkyl alcohol amide group with a carbon atomic number of 2-20. Unless otherwise specified, the term “substituted or unsubstituted” mentioned in the embodiments of the present disclosure refers to the hydrogen on the carbon atom being replaced or unsubstituted by F, Cl, Br, or I.

By modifying whisker 12 with the above-mentioned modification groups, not only can the dispersibility of whisker 12 in the resin be improved, but also due to the formation of sulfonic acid or phosphate ester shell layers on the surface of whisker particles, it can protect whisker particles and enhance their toughness, thereby preventing whisker 12 from fracture. In addition, the surface modified whisker 12 has an organic layer connected to its surface, which inhibits the growth of its short axis while maintaining the growth of its long axis. This increases the aspect ratio of whisker 12, further reducing the probability of whisker 12 breaking during stirring, and improving the chromaticity perspective of polarizing functional layer 11 to improve performance.

In some embodiments, the R group can be a substituted or unsubstituted alkyl chain, which can inhibit the growth of the short axis of whisker particles and increase the aspect ratio of whisker 12. Specifically, the general formula for the structure of R is, where R₁, R₂, and R₃ are independently selected from F, Cl, Br, I, or H, and n is an integer from 1 to 19. Modifying the end of the long chain with halogen atoms can enhance the stability of whisker 12.

Optionally, n can take values of 2, 3, 4, 5, 6, 7, 8, 9, 10, 11, 12, 13, 14, 15, 16, 17, 18.

In some embodiments, R_{1,} R₂, and R₃ are independently selected from For H, and at least one of R₁, R₂, and R₃ is selected from F. On the one hand, the F—C bond has high energy and is difficult to break. On the other hand, F atoms have a shielding effect on the C—C bond.

R₁, R₂, and R₃ are all selected from F, where the terminal group of R is perfluorinated. The radius of the F atom is larger than that of the hydrogen atom, which can effectively shield and protect the perfluorinated C—C bond, reducing the probability of C—C bond destruction. And while protecting the C—C bond, the radius of the F atom is not large enough to cause steric tension in the perfluorocarbon chain, so the fluorocarbon chain will be more stable.

In some embodiments, A is selected from substituted or unsubstituted aromatic groups with a ring atomic number of 6-20, such as phenyl, biphenyl, or naphthyl. The steric hindrance of the benzene ring is relatively large, and there is an organic protective layer containing the benzene ring on the surface of whisker 12. During the mixing and stirring process of whisker 12 and resin, this organic protective layer will buffer the mutual forces, thereby preventing the fracture of whisker 12 during the stirring process.

Optionally, X is a sulfonic acid group. During the stirring process, the sulfonic acid shell formed on the surface of whisker 12 can protect whisker 12 and prevent its fracture, thereby enhancing the toughness of whisker 12.

The modified group selects at least one of the following structural formulas:

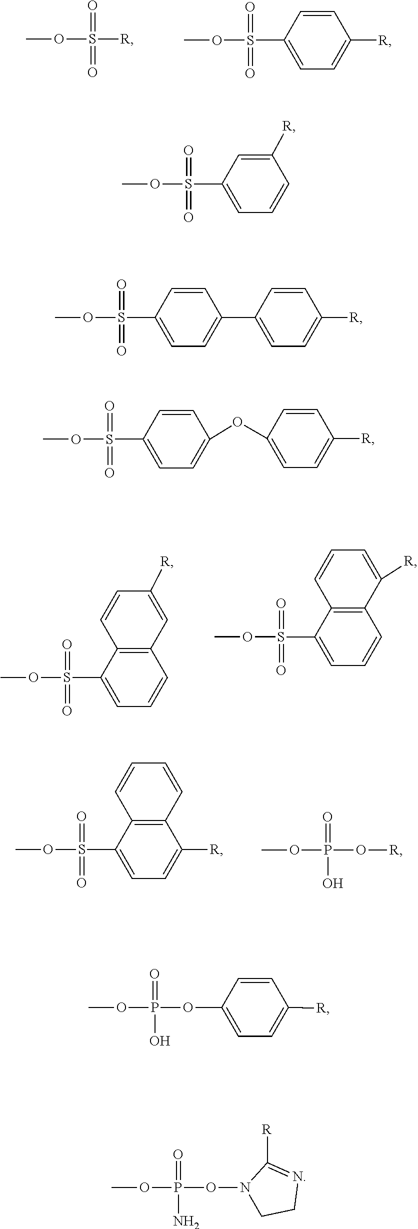

Furthermore, the modified group selects at least one of the following structural formulas:

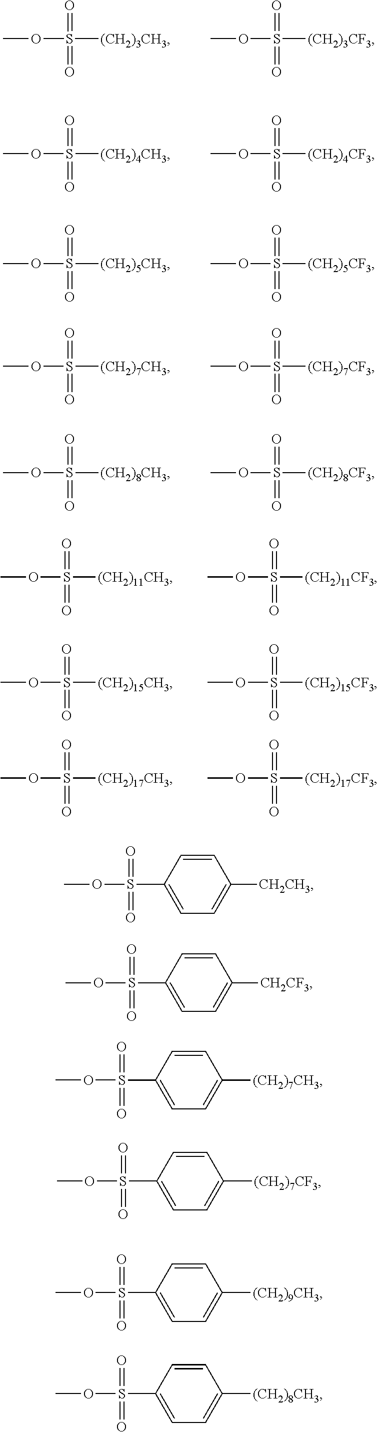

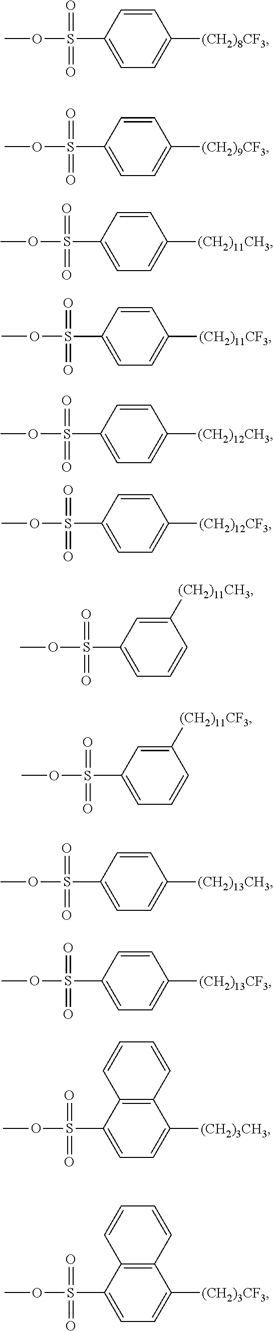

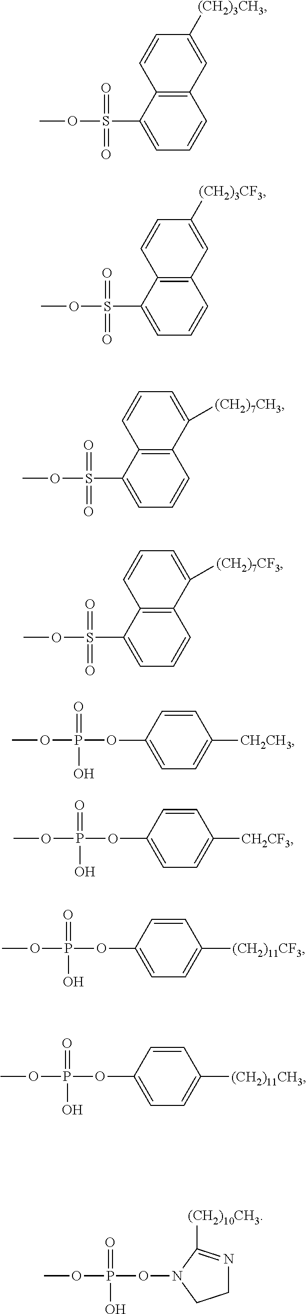

The above modified groups are only as examples, and the modified groups in the present disclosure are not limited to them. The modifier for modifying whisker 12 can be selected corresponding to the modification groups listed above. The modifier can be at least one of alkyl sulfonates, fluorinated alkyl sulfonates, aromatic alkyl phosphates, fluorinated aromatic alkyl phosphates, alkyl phosphates, alkyl phosphates, aromatic alkyl phosphates, aromatic alkyl phosphates, alkyl amide phosphates, alkyl amide phosphates, imidazoline phosphates, imidazoline phosphates, siloxane phosphates, high polymer phosphates, and high polymer phosphates.

Specifically, the modifier can be sodium dodecyl sulfonate, sodium perfluoro-1-dodecyl sulfonate, sodium 4-dodecylbenzene sulfonate, sodium 3-decylbenzene sulfonate, sodium 1-decane sulfonate, sodium perfluoro-1-decane sulfonate, sodium 1-butane sulfonate, sodium perfluoro-1-butane sulfonate, sodium 1-octane sulfonate, sodium perfluoro-1-octane sulfonate, sodium nonane sulfonate, sodium perfluoro-1-nonane sulfonate, sodium pentane sulfonate, sodium perfluoro-1-pentane sulfonate, and sodium 1-heptane sulfonate At least one of perfluoro-1-heptane sulfonate sodium, perfluoro-1-hexadecane sulfonate sodium, perfluoro-1-hexadecane sulfonate sodium, perfluoro-1-octadecane sulfonate sodium, 4-ethylbenzene sulfonate sodium, sunflower benzene sulfonate sodium, p-ethylbenzene sulfonate sodium, 4-octylbenzene sulfonate sodium, and butyl naphthalene sulfonate sodium.

The present disclosure also comprises a modification method for whisker 12, including the step B1, step B2 and step B3.

At step B1, disperse the main body of the whisker into the dispersion to form a suspension of the main body of the whisker.

At step B2, add a modifier to the suspension of the main body of the whisker while stirring to modify the whisker 12 to obtain a mixture.

At step B3, Remove impurities from the mixture to obtain whisker 12.

The dispersion can be a weakly alkaline or alkaline solvent, and the dispersion comprises at least one of sodium hydroxide, deionized water, methanol, ethylene glycol, glycerol, n-butanol, sec-butanol, and ammonia water.

In step B1, the mass fraction of whisker 12 in the suspension is 5% to 20%, which can be 5%, 6%, 7%, 8%, 9%, 10%, 12%, 13%, 15%, 16%, 17%, 18%, 19%, and 20%. The ratio of modifier to dispersion can be 0.5:1-1:1, specifically 0.5:1, 0.8:1, 0.9:1, or 1:1.

In steps B1 and B2, the control system temperature is between 65° C. and 75° C., which can be 65° C., 68° C., 70° C., 72° C. or 75° C. In step B20, the stirring rate can be 700 r/min˜900 r/min, which can be 700 r/min, 720 r/min, 740 r/min, 750 r/min, 760 r/min, 780 r/min, 800 r/min, 810 r/min, 820 r/min, 850 r/min, 860 r/min, 880 r/min or 900 r/min. The modification time (reaction time) can be 40 min˜80 min, which can be 40 min, 50 min, 55 min, 60 min, 65 min, 70 min or 80 min.

The impurity removal treatment steps include: filtering the mixture in sequence, cleaning with water, filtering, alcohol cleaning, followed by vacuum drying, and grinding to obtain modified whiskers 12.

In the above modification method, stirring is used to fully contact the modifier and the whisker body in the dispersion for modification. In this process, the —OH in the dispersion causes the atoms on the surface of the main body of the whisker to dissolve and be exposed. At this time, the functional groups in the modifier will form an interaction force with the exposed surface atoms to adsorb on the surface of the main body of the whisker. By adjusting the temperature of the system, the concentration of the modifier, and the stirring speed, the size of the interaction force is adjusted, and the morphology of the whisker 12 is adjusted.

Specifically, the modification of calcium carbonate whiskers using alkyl benzene sulfonic acid and alkyl phosphate ester modifiers is illustrated as examples.

The modification mechanism of alkyl benzene sulfonic acid type modifiers is shown in FIG. 5. Compared with ordinary modifiers, alkyl benzene sulfonic acid based modifiers can effectively enhance the toughness of calcium carbonate whiskers. During the stirring process, a benzene ring sulfonic acid based shell layer is formed on the surface of whiskers 12, which can protect the calcium carbonate whiskers and prevent them from breaking, thus achieving toughening effect; On the other hand, due to the presence of an organic layer on the surface of calcium carbonate whiskers, the growth of the short axis of calcium carbonate whiskers is inhibited, while the growth of the long axis is not affected. Therefore, it increases the aspect ratio of calcium carbonate whiskers, thereby preventing their fracture during the stirring process. In addition, long chains can also enhance the dispersion performance of calcium carbonate whiskers in the resin.

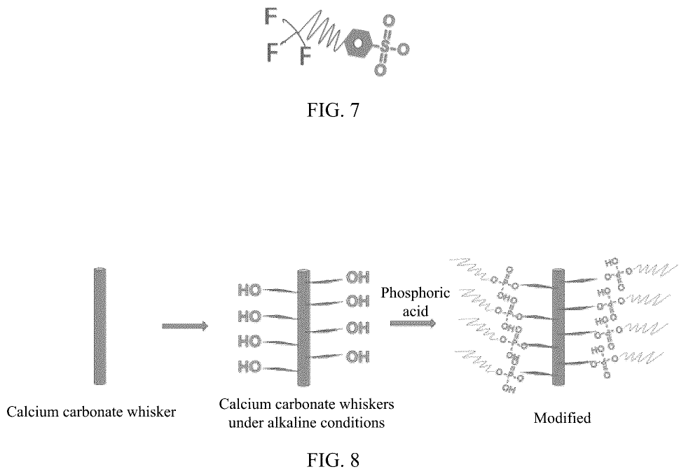

Furthermore, when the H atom on the end group of alkyl sulfonic acid modifiers or alkyl benzene sulfonic acid modifiers is completely replaced by F atoms, the stability of calcium carbonate whiskers can be enhanced. The modified groups on the surface of calcium carbonate whiskers can be seen in FIGS. 6 and 7.

On the one hand, the F—C bond has high energy and is difficult to break, and on the other hand, the F atom has a shielding effect on the C—C bond, which can reduce the probability of C—C being broken.

The modification mechanism of alkyl phosphate ester modifiers is similar to that of alkyl sulfonic acid based modifiers, as shown in FIG. 8.

It should be noted that the refractive index of whisker 12 after modification does not change significantly, and the difference in refractive index between the pre modified and post modified whiskers 12 can be ignored. The refractive index of whisker 12 is 1.5-2.0. Optionally, the refractive index of whisker 12 is 1.5, 1.55, 1.60, 1.65, 1.67, 1.68, 1.70, 1.75, 1.80, 1.85, 1.90, 1.95, or 2.0.

The difference in refractive index between whisker 12 and polarizing functional layer 11 is greater than 0 and less than or equal to 0.5. Specifically, the refractive index of whisker 12 is 0.18, 0.23, 0.28, or 0.43 higher than that of polarizing functional layer 11. Within this range, the effect of expanding the chromaticity perspective of the polarizing functional layer 11 is good.

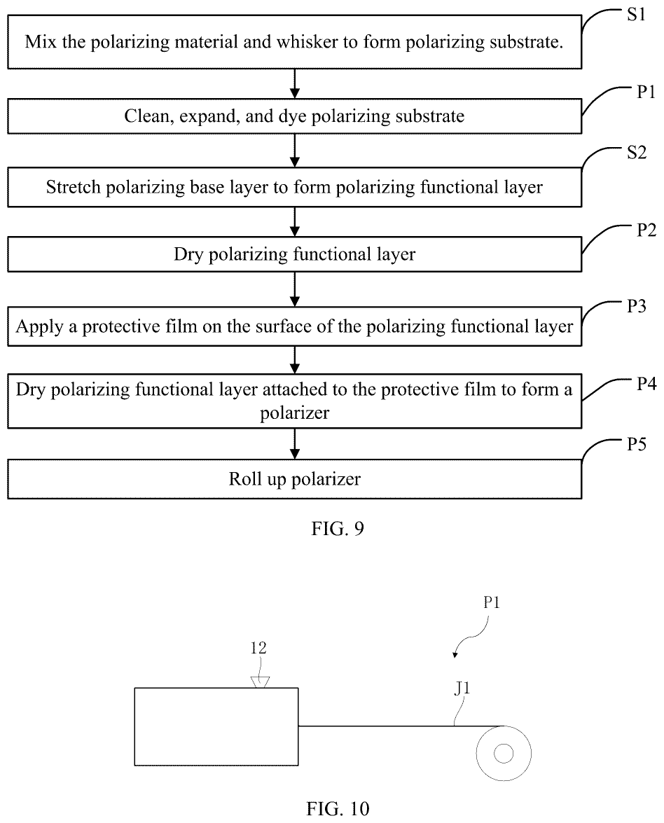

Please refer to FIG. 9, which is a flowchart of the preparation method for the polarizer 10 provided in an embodiment of the present disclosure. Correspondingly, an embodiment of the present disclosure also provides a preparation method for a polarizer 10, comprising the following steps:
Step S1, mixing the polarizing material and whisker 12 to form the polarizing substrate J1. Whisker 12 has a long axis.
Step S2, stretching the polarizing substrate J1 to form the polarizing functional layer 11, so that the angle between the extension direction of the long axis and the absorption axis Z of the polarizing functional layer is −5 degrees to 5 degrees.

The preparation method of the polarizer 10 provided in an embodiment of the present disclosure involves mixing whiskers 12 in the polarizing material to form a polarizing substrate J1, and then stretching the polarizing substrate J1 including whiskers 12 through a stretching process, so that the polarizing substrate J1 has a polarizing effect. At the same time, the whiskers 12 in the polarizer 10 change from disordered arrangement to ordered arrangement. The polarizer 10 formed in this way can cause the light passing through the polarizer 10 to undergo Mie scattering in the direction perpendicular to the absorption axis Z. When the polarizer 10 is attached to the display film layer, the viewing angle of the display panel 100 expands in the direction perpendicular to the absorption axis Z, and the contrast of the display panel 100 increases in the large viewing angle.

The following describes the preparation method of the polarizer 10 in this embodiment.

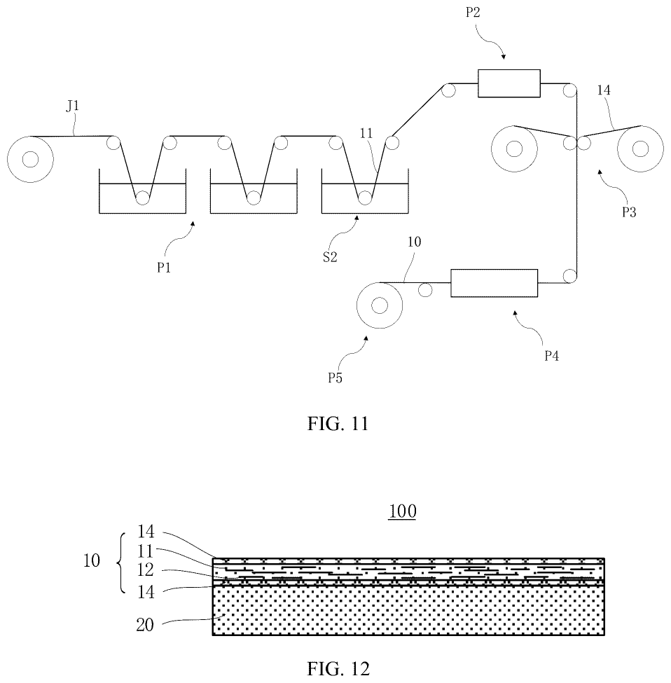

Please refer to FIGS. 9 to 11. At step S1, mix the polarizing material and whisker 12 to form the polarizing substrate J1. The whisker 12 has a long axis.

In this embodiment, the long axis of whisker 12 mixed in polarizing substrate J1 is 5 microns to 100 microns, and the short axis is 0.1 microns to 10 microns.

When forming a polarizing substrate J1, whiskers 12 are mixed in the polarizing material, with the long axis of whiskers 12 ranging from 5 microns to 100 microns and the short axis ranging from 0.1 microns to 10 microns. Then shape and solidify the mixed material to form a polarizing substrate J1.

Optionally, the proportion of whisker 12 in the polarizing material is M3, with 0%<M3<30%, where M3 can be 5%, 6%, 7%, 8%, 10%, 15%, or 20%.

In this embodiment, 7 wt % of whiskers 12 are mixed in the polarizing material to form a polarizing substrate J1. The mass percentage of whiskers 12 in the polarizer 10 formed by this polarizing substrate J1 is about 10 wt %, which can expand the viewing angle of the display screen to over 160 degrees.

When the proportion of whiskers 12 added to the polarizing material is relatively small, the scattering effect of the polarizing plate 10 formed is weak, which can improve the contrast of the side view angle of the display panel 100. However, there is still a gap between the contrast of the side view angle and the contrast of the front view angle. When a large proportion of whiskers 12 are added to the polarizing material, the formed polarizer 10 has a strong scattering effect, with more light scattered to the side view angle, resulting in a decrease in the light transmittance of the front of the polarizer 10, resulting in a lower brightness of the positive view angle screen.

Optionally, the polarizing material can be polyvinyl alcohol (PVA), and whisker 12 is selected from one of calcium carbonate whiskers, barium sulfate whiskers, titanium oxide whiskers, and alumina whiskers, but the present disclosure is not limited to this. Whisker 12 can also be selected from other materials, such as zirconia, zinc oxide, boehmite, aluminum borate, calcium silicate, magnesium sulfate, magnesium sulfate hydrate, potassium titanate, etc.

Optionally, after forming the polarizing substrate J1 in step S1, the preparation method of the polarizer 10 in this embodiment can also include step P1.

Step P1, clean, expand, and dye the polarizing substrate J1. Clean the organic impurities in the polarizing substrate JI and dye it to avoid the impact of impurities on the performance of the polarizing functional layer 11.

Then proceed to step S2. From step S1 to step P1, then to step S2, or step S1 directly to step S2.

Step S2, stretch the polarizing substrate J1 to form the polarizing functional layer 11, so that the angle between the extension direction of the long axis of the whisker 12 and the extension direction of the absorption axis Z of the polarizing functional layer is −5 degrees to 5 degrees.

Specifically, a roller is used to stretch the polarizing substrate J1, so that the angle between the extension direction of the long axis of the whisker 12 and the extension direction of the polarizing functional layer absorption axis Z is −5 degrees to 5 degrees. Among them, the stretching ratio is greater than 0 and less than 100, which can be 5 times, 10 times, 15 times, or 20 times.

Mixing whisker 12 into the polarizing material, stretching the polarizing substrate J1 while orienting whisker 12, the preparation process is simple. The polarizing functional layer 11 formed after dyeing and stretching has a polarizing effect, which can convert natural light into polarized light.

Optionally, in this embodiment, the preparation method of the polarizer 10 also comprises steps P2, P3, P4, and P5. Steps P2 to P5 follow step S2 in sequence.

At step P2, dry the polarizing functional layer 11.

At step P3, apply a protective film 14 on the surface of the polarizing functional layer 11.

At step P4, dry the polarizing functional layer 11 attached to the protective film 14 to form a polarizer 10.

At step P5, roll up the polarizer 10.

Continue to complete the preparation of polarizer 10, and proceed from step S2 to step P2.

At step P2, dry the polarizing functional layer 11.

In this embodiment, after the polarizing functional layer 11 is dried, the percentage of the mass of whisker 12 in the polarizing functional layer 11 to the total mass of the polarizing functional layer 11 is M1, with 0%<M1<80%. For example, M1 is 8%, 10%, 15%, 20%, 25%, 30%, 50%, or 60%.

Drying the polarizing functional layer 11 can remove water vapor in the polarizing functional layer 11, thereby increasing the mass percentage of whisker 12 in the polarizing functional layer 11.

Then proceed to step P3.

At step P3, apply a protective film 14 on the surface of the polarizing functional layer 11.

Specifically, the protective film 14 can be made of Triacetyl Cellulose (TAC) film to protect the polarizing functional layer 11.

Then proceed to step P4.

At step P4, dry the polarizing functional layer 11 attached to the protective film 14 to form a polarizer 10. Remove water vapor from protective film 14.

Then proceed to step P5.

At step P5, roll up the polarizer 10 for future attachment.

At this point, the preparation of the polarizer 10 in the embodiment of the present disclosure has been completed.

Please refer to FIG. 12. The present disclosure also provides a display panel 100, which comprises a panel body 20 and any of the aforementioned polarizing sheets 10 attached to the panel body 20, or a polarizer 10 prepared by a preparation method of any of the aforementioned polarizing sheets 10. The polarizer 10 comprises a polarizing functional layer 11 and a whisker 12 arranged within the polarizing functional layer 11. The polarized functional layer 11 after dyeing and stretching is used to convert natural light into polarized light. Whiskers 12 are directionally arranged within the polarizing functional layer 11. The polarizing functional layer 11 has an absorption axis Z. Whisker 12 has a long axis, and the angle between the extension direction of the long axis and the absorption axis Z of the polarizing functional layer is −5 degrees to 5 degrees. Among them, whisker 12 is selected from at least one of calcium carbonate whiskers, barium sulfate whiskers, titanium oxide whiskers, alumina whiskers, zirconia whiskers, zinc oxide whiskers, boehmite whiskers, aluminum borate whiskers, calcium silicate whiskers, magnesium sulfate whiskers, magnesium sulfate hydrate whiskers, and potassium titanate whiskers. The material of the polarizing functional layer 11 comprises polyvinyl alcohol.

The above provides a detailed introduction to a polarizer 10 and its preparation method, as well as a display panel 100 provided in the embodiment of the present disclosure.

The polarizer provided in the embodiment of the present disclosure comprises a polarizing functional layer and a whisker arranged within the polarizing functional layer. The polarizing functional layer is used to convert natural light into polarized light. Whiskers are directionally arranged in the polarizing functional layer, and have a long axis. The angle between the extension direction of the long axis and the absorption axis of the polarizing functional layer is −5 degrees to 5 degrees. The embodiment of the present disclosure also provides a preparation method for a polarizer and a display panel including a polarizer.

The embodiments of the present disclosure propose stretching the polarizing substrate containing whiskers during the preparation process, the polarizing substrate has a polarizing effect while changing the disordered arrangement of whiskers into an ordered arrangement. The polarizer formed in this way has an angle between −5 degrees and 5 degrees between the long axis extension direction of the whisker and the absorption axis extension direction of the polarizing functional layer. The arrangement of whiskers in the polarizer will cause Mie scattering of light to pass through the polarizer in the direction perpendicular to the absorption axis. When the polarizer is attached to the display film layer, the visual angle of the display panel expands in the direction perpendicular to the absorption axis, which means the viewing range is expanded. At the same time, the chromaticity angle is improved, so that the chromaticity and hue under a large viewing angle are close to those under a positive viewing angle, and the display quality is improved.

Above are embodiments of the present disclosure, which does not limit the scope of the present disclosure. Any modifications, equivalent replacements or improvements within the spirit and principles of the embodiment described above should be covered by the protected scope of the disclosure.

1. A polarizer, comprising:
a polarizing functional layer, for converting natural light into polarized light; and
whiskers, directionally arranged within the polarizing functional layer;
wherein each of the whiskers has a long axis, and an extension direction of the long axis has an angle of −5 degrees to 5 degrees with an absorption axis of the polarizing functional layer.

2. The polarizer as claimed in claim 1, wherein the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker.

3. The polarizer as claimed in claim 1, wherein a material of the polarizing functional layer comprises polyvinyl alcohol.

4. The polarizer as claimed in claim 1, wherein a mass percentage of the whisker in the polarizing functional layer is M1, 0%<M1<80%.

5. The polarizer as claimed in claim 4, wherein the whisker accounts for a mass percentage of 10% of the polarizing functional layer.

6. The polarizer as claimed in claim 1, wherein an acute angle is formed between the extension direction of the long axis of the whisker and the bottom surface of the polarizing functional layer, and the acute angle is greater than 0 degree and less than or equal to 40 degrees.

7. The polarizer as claimed in claim 6, wherein the acute angle is greater than 0 degree and less than or equal to 20 degrees.

8. The polarizer as claimed in claim 1, wherein the long axis is 5 microns to 100microns, the whisker has a short axis, and the short axis is 0.5 microns to 1 microns.

9. The polarizer as claimed in claim 1, wherein the whisker comprises a main body and a modified group connected to the surface of the main body, the structural formula of the modified group is —X—A—R, where X is selected from SO₃ or PO₄H, A is selected from a single bond, a substituted or unsubstituted aromatic group with a ring atomic number of 6-20, or an imidazoline group, and R is selected from a substituted or unsubstituted alkyl group with a carbon atomic number of 2-20, and a substituted or unsubstituted siloxane alkyl group with a carbon atomic number of 2-20, Alkyl alcohol amide groups with a carbon atom number of 2-20.

10. The polarizer as claimed in claim 9, wherein the general structural formula of R is 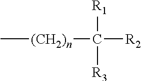
that R₁, R₂, and R₃ are independently selected from F, Cl, Br, I, or H, and n is an integer from 1 to 19.

11. The polarizer as claimed in claim 10, wherein R₁, R₂, and R₃ are independently selected from F or H, and at least one of R₁, R₂, and R₃ is selected from F; and/or
X selected from SO₃; and/or
A is selected from substituted or unsubstituted aromatic groups with a ring atomic number of 6-20.

12. The polarizer as claimed in claim 9, wherein the modified group is selected from at least one of the following structural formulas:

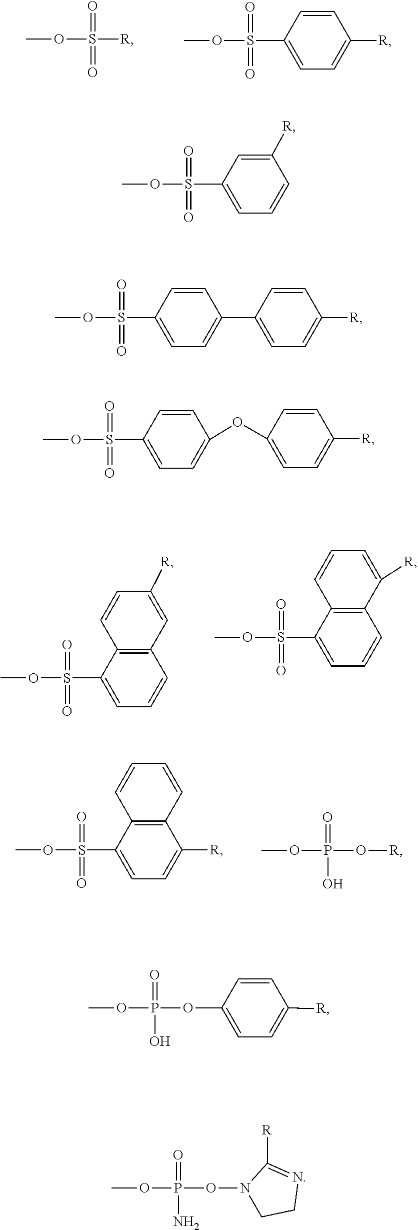

13. The polarizer according to claim 9, wherein a difference in refractive index between the whisker and the polarizing functional layer is greater than 0 and less than or equal to 0.5; and/or
the refractive index of the whisker is greater than or equal to 1.5 and less than or equal to 2.0.

14. A method for preparing a polarizer, comprising:
mixing polarizing materials and whiskers to form a polarizing substrate, wherein the whiskers have a long axis; and
stretching the polarizing base layer to form a polarizing functional layer, so that the whiskers are oriented and arranged, and the angle between the extension direction of the long axis and the absorption axis of the polarizing functional layer is −5 degrees to 5 degrees.

15. The method according to claim 14, wherein after the step of mixing the polarizing material and whiskers to form a polarizing base layer, and before the step of stretching the polarizing base layer to form a polarizing functional layer, the method further comprises: cleaning, expanding, and dyeing the polarizing base layer.

16. The method as claimed in claim 14, wherein the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker.

17. The method as claimed in claim 14, wherein a material of the polarizing functional layer comprises polyvinyl alcohol.

18. The method according to claim 14, wherein the whisker accounts for a mass percentage of 10% of the polarizing functional layer.

19. A display panel, comprising:
a panel body; and
a polarizer, attached to the panel body, the polarizer comprising:
a polarizing functional layer, for converting natural light into polarized light; and
whiskers, directionally arranged within the polarizing functional layer; wherein each of the whiskers has a long axis, and an extension direction of the long axis has an angle of −5 degrees to 5 degrees with an absorption axis of the polarizing functional layer.

20. The display panel as claimed in claim 19, wherein the whisker is selected from at least one of calcium carbonate whisker, barium sulfate whisker, titanium oxide whisker, alumina whisker, zirconia whisker, zinc oxide whisker, boehmite whisker, aluminum borate whisker, calcium silicate whisker, magnesium sulfate whisker, magnesium sulfate hydrate whisker, and potassium titanate whisker, and wherein a material of the polarizing functional layer comprises polyvinyl alcohol.
